(19) United States
(12) Patent Application Publication
(10) Pub. No.: US 2024/0357813 A1
(43) Pub. Date: Oct. 24, 2024

(54) SEMICONDUCTOR STORAGE DEVICE

(71) Applicant: Kioxia Corporation, Tokyo (JP)

(72) Inventors: Shizuka KUTSUKAKE, Kuwana Mie (JP); Katsumi MORII, Kato Hyogo (JP)

(73) Assignee: Kioxia Corporation, Tokyo (JP)

(21) Appl. No.: 18/616,201

(22) Filed: Mar. 26, 2024

(30) Foreign Application Priority Data
Apr. 20, 2023 (JP) 2023-069596

(51) Int. Cl. H10B 43/27; H01L 23/00; H01L 25/065; H01L 25/18; H10B 43/10; H10B 80/00

(52) U.S. Cl. CPC H10B 43/27; H01L 24/08; H01L 25/0657; H01L 25/18; H10B 43/10; H10B 80/00; H01L 2224/08145; H01L 2924/1431; H01L 2924/14511

(57) ABSTRACT

A semiconductor storage device according to the present embodiment includes a stacked body including a plurality of first conducting films and a plurality of first insulating films alternately stacked in a first direction. A plurality of columnar bodies each include a first semiconductor part extending in the first direction in the stacked body, and a first insulator part located between the first semiconductor part and the stacked body. A transistor is located in the first direction of the stacked body. A plurality of first conductors extend in the first direction and are connected to the transistor. Three adjacent ones of the first conductors are arranged to form an equilateral triangle in a first plane orthogonal to the first direction.

### CROSS REFERENCE TO RELATED APPLICATIONS

This application is based upon and claims the benefit of priority from the prior Japanese Patent Application No. 2023-069596, filed on Apr. 20, 2023, the entire contents of which are incorporated herein by reference.

### FIELD

The embodiments of the present invention relate to a semiconductor storage device.

### BACKGROUND

Some semiconductor storage devices such as a NAND flash memory have a three-dimensional memory cell array in which a plurality of memory cells are arranged three-dimensionally. In such a three-dimensional memory cell array, a plurality of word line contacts are formed to depths of a plurality of stacked word lines associated therewith. Contacts connected to bonding pads provided around the memory cell array are arranged at a high density to decrease the resistances.

When the word line contacts with various depths and the contacts at a high density are formed at the same time, the contact holes for the contacts at a high density are hard to penetrate. If the contact holes for the contacts at a high density are attempted to sufficiently penetrate, the contact holes for shallow word line contacts pierce through the word lines.

### BRIEF DESCRIPTION OF THE DRAWINGS

FIG. 1 is a sectional view illustrating a configuration example of a semiconductor storage device according to a first embodiment;

FIG. 2 is a schematic plan view illustrating a stacked body;

FIG. 3 is a schematic sectional view illustrating memory cells in a three-dimensional structure;

FIG. 4 is a schematic sectional view illustrating the memory cells in a three-dimensional structure;

FIG. 5 is a schematic plan view of an array chip;

FIG. 6 is a schematic plan view of a CMOS chip;

FIG. 7 is a plan view illustrating arrangement of contact plugs and a bonding pad provided in a pad region of the array chip;

FIG. 8 is a plan view illustrating arrangement of the contact plugs and the bonding pad provided in the pad region of the array chip;

FIG. 9 is a plan view illustrating a region of the contact plugs;

FIG. 10 is a plan view illustrating an arrangement example of the contact plugs in more detail;

FIG. 11 is a plan view illustrating an arrangement example of three adjacent contact plugs;

FIG. 12 is a plan view illustrating an arrangement example of contact plugs connected to word lines at stepped portions, and supporting posts;

FIG. 13 is a plan view illustrating an arrangement example of the contact plugs;

FIG. 14 is a plan view illustrating an arrangement example of four adjacent contact plugs;

FIG. 15 is a sectional view illustrating a configuration example of a semiconductor storage device according to a second embodiment;

FIG. 16 is a block diagram illustrating a configuration example of a semiconductor storage device; and

FIG. 17 is a circuit diagram illustrating an example of a circuit configuration of a memory cell array.

### DETAILED DESCRIPTION

In general, according to the embodiment, a semiconductor storage device includes a stacked body including a plurality of first conducting films and a plurality of first insulating films alternately stacked in a first direction. A plurality of columnar bodies each include a first semiconductor part extending in the first direction in the stacked body, and a first insulator part located between the first semiconductor part and the stacked body. A transistor is located in the first direction of the stacked body. A plurality of first conductors extend in the first direction and are connected to the transistor. Three adjacent ones of the first conductors are arranged to form an equilateral triangle in a first plane orthogonal to the first direction.

Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

Embodiments according to the present invention will be explained below with reference to the drawings. The present invention is not limited to the embodiments. The drawings are schematic or conceptual. In the present specification and the drawings, identical elements are denoted by like reference characters.

### First Embodiment

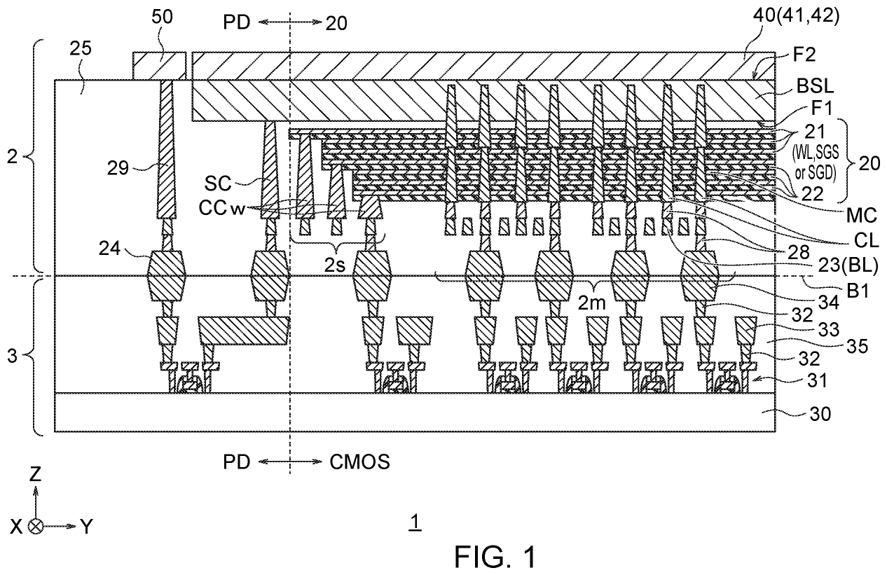

FIG. 1 is a sectional view illustrating a configuration example of a semiconductor storage device 1 according to a first embodiment. Hereinafter, the stacking direction of a stacked body 20 is assumed as a Z direction. One direction intersecting with, for example, orthogonal to the Z direction is assumed as a Y direction. One direction intersecting with, for example, orthogonal to the Z direction and the Y direction is assumed as an X direction. In the present specification, the X direction is an example of a third direction, the Y direction is an example of a second direction, and the Z direction is an example of a first direction.

The semiconductor storage device 1 includes an array chip 2 including a memory cell array, and a CMOS (Complementary Metal-Oxide-Semiconductor) chip 3 including a CMOS circuit. The array chip 2 and the CMOS chip 3 are bonded on a bonding face B1 and are electrically connected to each other via a line joined on the bonding face B1. FIG. 1 illustrates a state in which the array chip 2 is placed on the CMOS chip 3.

The CMOS chip 3 includes a substrate 30, transistors 31, vias 32, lines 33 and 34, and an interlayer dielectric film 35.

The substrate 30 is, for example, a semiconductor substrate such as a silicon substrate. The transistors 31 are NMOS or PMOS transistors placed on the substrate 30. The transistors 31 constitute, for example, CMOS circuits that control the memory cell array on the array chip 2. A plurality of the transistors 31 constitute logic circuits such as sense amplifiers, row decoders, and column decoders. Semiconductor elements such as a resistive element and a capacitive element, other than the transistors 31 may be formed on the substrate 30.

The vias 32 electrically connect between the transistors 31 and the lines 33 or between the lines 33 and the lines 34. The lines 33 and 34 constitute a multilayer wiring structure in the interlayer dielectric film 35. The lines 34 are embedded in the interlayer dielectric film 35 and are exposed on the surface of the interlayer dielectric film 35 to be substantially flush with the surface. The lines 33 and 34 are electrically connected to the transistors 31, or the like. For example, a low-resistance metal such as copper or tungsten is used for the vias 32, and the lines 33 and 34. The interlayer dielectric film 35 covers and protects the transistors 31, the vias 32, and the lines 33 and 34. For example, an insulating film such as a silicon dioxide film is used for the interlayer dielectric film 35.

The array chip 2 includes a stacked body 20, columnar bodies CL, slits ST(LI), a source layer BSL, a metallic layer 40, contact plugs CCw, contact plugs 29, and bonding pads 50.

The stacked body 20 is provided above the transistors 31 and is positioned in the Z direction with respect to the substrate 30. The stacked body 20 is configured by alternately stacking a plurality of electrode films 21 and a plurality of insulating films 22 along the Z direction. The stacked body 20 constitutes the memory cell array. For example, a conductive metal such as tungsten is used for the electrode films 21. For example, an insulating film such as a silicon dioxide film is used for the insulating films 22. The insulating films 22 insulate the electrode films 21 from each other. That is, the electrode films 21 are stacked in a mutually insulated state. The numbers of the stacked electrode films 21 and the stacked insulating films 22 can be freely selected. The insulating films 22 may be, for example, porous insulating films or air gaps.

One or a plurality of the electrode films 21 on the upper end and the lower end of the stacked body 20 in the Z direction function as source-side selection gates SGS and drain-side selection gates SGD, respectively. Electrode films 21 between the source-side selection gates SGS and the drain-side selection gates SGD function as word lines WL. The word lines WL are gate electrodes of memory cells MC. The drain-side selection gates SGD are gate electrodes of drain-side selection transistors. The source-side selection gates SGS are provided in an upper region of the stacked body 20. The drain-side selection gates SGD are provided in a lower region of the stacked body 20. The upper region indicates a region of the stacked body 20 near the CMOS chip 3 and the lower region indicates a region of the stacked body 20 far from the CMOS chip 3 (near the metallic layer 40).

The semiconductor storage device 1 has a plurality of memory cells MC connected in series between the source-side selection transistor and the drain-side selection transistor. A structure in which the source-side selection transistor, the memory cells MC, and the drain-side selection transistor are connected in series is referred to as “memory string” or “NAND string”. The memory string is connected to, for example, one of bit lines BL through a vias 28. The bit lines BL are lines 23 provided below the stacked body 20 and extending in the X direction (the depth direction of the drawing in FIG. 1).

A plurality of columnar bodies CL are provided in the stacked body 20. The columnar bodies CL extend in the stacked body 20 to penetrate through the stacked body 20 in the stacking direction (the Z direction) of the stacked body and are each provided from the associated via 28 connected to the bit line BL to the source layer BSL. An internal structure of the columnar bodies CL will be described later. Since the columnar bodies CL have a high aspect ratio in the present embodiment, each of the columnar bodies CL is formed in two tiers in the Z direction. However, there is no problem with the columnar bodies CL in one tier.

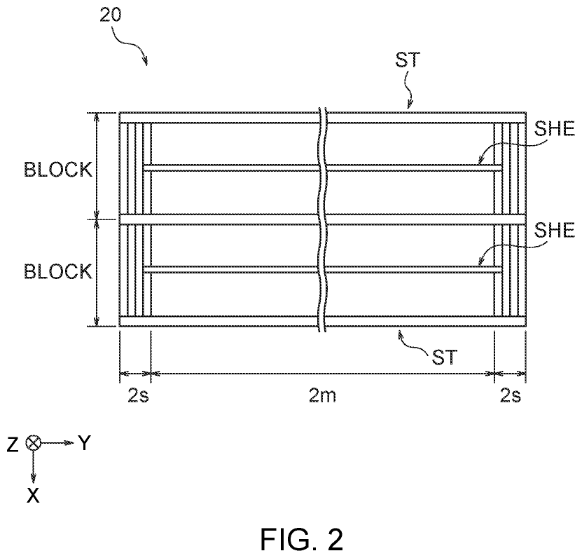

Although not illustrated in FIG. 1, a plurality of slits ST (see FIG. 2) are provided in the stacked body 20. The slits ST extend in the Y direction and penetrate through the stacked body 20 in the stacking direction (the Z direction) of the stacked body 20. In each of the slits ST, an insulating film such as a silicon dioxide film is filled and the insulating film is formed in a plate manner. The slits ST electrically isolate the electrode films 21 of the stacked body 20. It is alternatively possible that the inner wall of each of the slits ST is coated with an insulating film such as a silicon dioxide film and that a conducting material is further filled inside the insulating film. In this case, the conducting material functions also as a source line reaching the source layer BSL.

The source layer BSL is provided on the stacked body 20. The source layer BSL is an example of a first semiconductor layer. The source layer BSL is provided corresponding to the stacked body 20. The source layer BSL has a first face F1, and a second face F2 on the opposite side to the first face F1. The stacked body 20 (the memory cell array) is provided on the side of the first face F1 of the source layer BSL, and the metallic layer 40 is provided on the side of the second face F2. The metallic layer 40 includes a source line 41 and a power-supply line 42. The source layer BSL is connected in common to one ends of the columnar bodies CL and supplies a common source potential to a plurality of the columnar bodies CL in the same memory cell array 2m. That is, the source layer BSL functions as a common source electrode for the memory cell array 2m. For example, a conductive material such as doped polysilicon is used for the source layer BSL. For example, a metallic material of a lower resistance than that of the source layer BSL, such as copper, aluminum, or tungsten is used for the metallic layer 40. Reference sign 2s denotes a stepped portion of the electrode films 21 provided to connect contacts to the electrode films 21. The stepped portion 2s will be described later with reference to FIG. 2.

Meanwhile, the bonding pads 50 are provided above the stacked body 20 in a region where the source layer BSL is not provided. The bonding pads 50 are connected to metallic wires (not illustrated) or the like to receive power supply or a signal from outside of the semiconductor storage device 1. The bonding pads 50 are provided to be connected to one ends of the contact plugs 29 in the Z direction. The bonding pads 50 are connected to the transistors 31 of the CMOS chip 3 via the contact plugs 29, and the lines 24 and 34. Accordingly, external power supplied from the bonding pads 50 is supplied to the transistors 31. Alternatively, a signal is supplied to the transistors 31 or the memory cell array 2m via the bonding pads 50.

The contact plugs CCw are provided in a peripheral part of the stacked body 20 and extends in the Z direction in an interlayer dielectric film 25. Each of the contact plugs CCw is electrically connected between the associated electrode film 21 (the word line WL) and the line 24. The contact plugs CCw are provided at the stepped portions 2s each formed stepwise at an end part of the stacked body 20, and are each electrically connected to the associated electrode film 21. The contact plugs CCw are provided to transfer a word line voltage from the CMOS chip 3 to the associated electrode films 21. For example, a low-resistance metal such as copper or tungsten is used for the contact plugs CCw.

The contact plugs 29 are provided in a peripheral part of the stacked body 20 and extend in the Z direction in the interlayer dielectric film 25. The contact plugs 29 are contact plugs each provided from the associated line 24 to the bonding pad 50. The contact plugs 29 are simultaneously formed in the same process as that for the contact plugs CCw connected to the word lines WL.

The contact plugs 29 are each electrically connected between the bonding pad 50 and the line 24. The contact plugs 29 are used to supply a power-supply voltage or a signal from the bonding pad 50 to the array chip 2 or the CMOS chip 3. For example, a low-resistance metal such as copper or tungsten is used for the contact plugs 29. The power-supply voltage can be a power-supply voltage VDD being a high-level voltage or a reference voltage (for example, a ground voltage) VSS being a low-level voltage. The signal may be a control signal from outside, or may be data to be written or read data.

In the present embodiment, the array chip 2 and the CMOS chip 3 are formed individually and bonded on the bonding face B1. Therefore, the transistors 31 are not provided in the array chip 2. The stacked body 20 (the memory cell array) is not provided in the CMOS chip 3. The transistors 31 and the stacked body 20 are both on the side of the first face F1 of the source layer BSL. The transistors 31 are located on the opposite side to the second face F2 where the metallic layer 40 is located.

The vias 28, the lines 23, and the lines 24 are provided below the stacked body 20. The lines 23 and 24 are embedded in the interlayer dielectric film 25. The lines 24 are exposed on the surface of the interlayer dielectric film 25 to be substantially flush with the surface. The lines 23 and 24 are electrically connected to semiconductor bodies 210 of the columnar bodies CL, or the like. For example, a low-resistance metal such as copper or tungsten is used for the vias 28, the lines 23, and the lines 24. The interlayer dielectric film 25 covers and protects the stacked body 20, the vias 28, the lines 23, and the lines 24. For example, an insulating film such as a silicon dioxide film is used for the interlayer dielectric film 25.

The interlayer dielectric film 25 and the interlayer dielectric film 35 are bonded on the bonding face B1 and are also joined to the lines 24 and the lines 34 on the bonding face B1 to be substantially flush therewith. Accordingly, the array chip 2 and the CMOS chip 3 are electrically connected via the lines 24 and the lines 34.

FIG. 2 is a schematic plan view illustrating the stacked body 20. The stacked body 20 includes the stepped portions 2s and the memory cell array 2m. The stepped portions 2s are provided at the end parts of the stacked body 20. The memory cell array 2m is sandwiched or surrounded by the stepped portions 2s. The slits ST(LI) are provided from the stepped portion 2s at one end of the stacked body 20 through the memory cell array 2m to the stepped portion 2s at the other end of the stacked body 20. Slits SHE are provided at least in the memory cell array 2m. The slits SHE are shallower than the slits ST(LI) and extend substantially in parallel to the slits ST(LI). Each of the slits SHE is provided to electrically isolate the electrode films 21 for each of the drain-side selection gates SGD. Alternatively, the slits ST may be source lines LI electrically isolated from the electrode films 21 of the stacked body 20 and electrically connected to the source layer BSL. That is, the slits ST may be the source lines LI that are electrically isolated from the electrode films 21 of the stacked body 20 constituting the memory cell array and that are electrically connected to the source layer BSL.

A portion of the stacked body 20 sandwiched by two slits ST illustrated in FIG. 2 is referred to as “block (BLOCK)”. A block constitutes, for example, a minimum unit of data erasing. The slits SHE are provided in the blocks. The stacked body 20 between the slit ST and the slit SHE is referred to as “finger”. The drain-side selection gate SGD is divided for each finger. Accordingly, at the time of writing and reading data, one finger in a block can be brought to a selected state by the associated drain-side selection gate SGD.

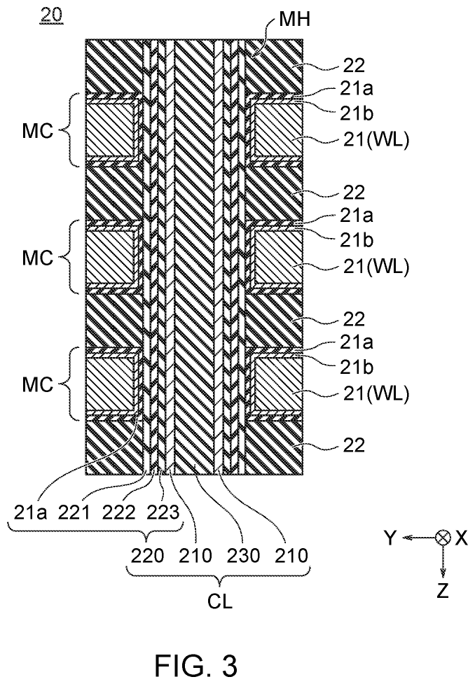

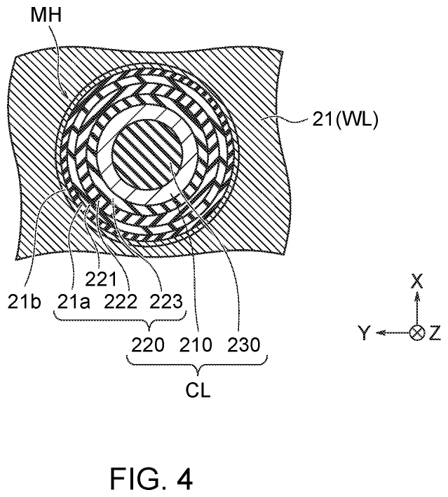

FIGS. 3 and 4 are schematic sectional views illustrating memory cells in a three-dimensional structure. Each of the columnar bodies CL is provided in a memory hole MH formed in the stacked body 20. Each of the columnar bodies CL penetrates through the stacked body 20 along the Z direction from the upper end of the stacked body 20 to be located in the stacked body 20 and the source layer BSL. Each of the columnar bodies CL includes the semiconductor body 210, a memory film 220, and a core layer 230. Each columnar body CL includes the core layer 230 located at the central part, the semiconductor body (a semiconductor member) 210 located around the core layer 230, and the memory film (a charge accumulating member) 220 located around the semiconductor body 210. The semiconductor body 210 extends in the stacking direction (the Z direction) in the stacked body 20. The semiconductor body 210 is electrically connected to the source layer BSL. The memory film 220 is located between the semiconductor body 210 and the electrode films 21, and has charge trapping parts. A plurality of the columnar bodies CL each selected from each finger are connected in common to one bit line BL through the vias 28 in FIG. 1. Each of the columnar bodies CL is provided, for example, in the region of the memory cell array 2m.

As illustrated in FIG. 4, the shape of the memory hole MH in an X-Y plane is, for example, circular or elliptic. A block dielectric film 21a constituting a part of the memory film 220 may be provided between the electrode films 21 and the insulating films 22. The block dielectric film 21a is, for example, a silicon oxide or a metal oxide. One example of the metal oxide is an aluminum oxide. A barrier film 21b may be provided between the electrode films 21 and the insulating films 22 and between the electrode films 21 and the memory film 220. A stacked film including titanium nitride and titanium is selected as the barrier film 21b in a case in which the electrode films 21 are tungsten. The block dielectric film 21a suppresses back tunneling of charges from the electrode films 21 to the memory film 220. The barrier film 21b improves adhesion between the electrode films 21 and the block dielectric film 21a.

The shape of the semiconductor body 210 is, for example, a bottomed tube. For example, polysilicon is used for the semiconductor body 210. The semiconductor body 210 is, for example, undoped silicon. The semiconductor body 210 may be p-type silicon. The semiconductor body 210 functions as channels of a drain-side selection transistor STD, the memory cells MC, and a source-side selection transistor STS. One ends of a plurality of the semiconductor bodies 210 in the same memory cell array 2m are electrically connected in common to the source layer BSL.

A portion of the memory film 220 other than the block dielectric film 21a is located between the inner wall of the memory hole MH and the semiconductor body 210. The shape of the memory film 220 is, for example, tubular. A plurality of the memory cells MC each have a storage region between the semiconductor body 210 and the associated electrode film 21 functioning as the word line WL and are stacked in the Z direction. The memory film 220 includes, for example, a cover dielectric film 221, a charge trapping film 222, and a tunnel dielectric film 223. Each of the semiconductor body 210, the charge trapping film 222, and the tunnel dielectric film 223 extends in the Z direction.

The cover dielectric film 221 is located between the insulating films 22 and the charge trapping film 222 and between the block dielectric film 21a and the charge trapping film 222. The cover dielectric film 221 includes, for example, a silicon oxide. The cover dielectric film 221 protects the charge trapping film 222 from being etched when sacrificial films (not illustrated) are replaced by the electrode films 21 (in a replacement process). When the replacement process is not used to form the electrode films 21, it is possible that the cover dielectric film 221 is not provided.

The charge trapping film 222 is located between the cover dielectric film 221 and the tunnel dielectric film 223. The charge trapping film 222 includes, for example, a silicon nitride and has a trap site that traps charges in the film. Portions of the charge trapping film 222 sandwiched between the electrode films 21 functioning as the word lines WL and the semiconductor body 210 constitute the storage regions of the memory cells MC as the charge trapping parts. A threshold voltage of each of the memory cells MC varies according to whether there are charges in the associated charge trapping part or the amount of charges trapped in the charge trapping part. This causes each of the memory cells MC to retain information.

The tunnel dielectric film 223 is located between the semiconductor body 210 and the charge trapping film 222. The tunnel dielectric film 223 includes, for example, a silicon oxide, or a silicon oxide and a silicon nitride. The tunnel dielectric film 223 is a potential barrier between the semiconductor body 210 and the charge trapping film 222. For example, when electrons are injected from the semiconductor body 210 to the charge trapping part (a write operation) and when positive holes are injected from the semiconductor body 210 to the charge trapping part (an erase operation), the electrons and the positive holes each pass through (tunnel) the potential barrier of the tunnel dielectric film 223.

The core layer 230 fills the internal space of the tubular semiconductor body 210. The shape of the core layer 230 is, for example, columnar. The core layer 230 includes, for example, a silicon oxide and is insulating.

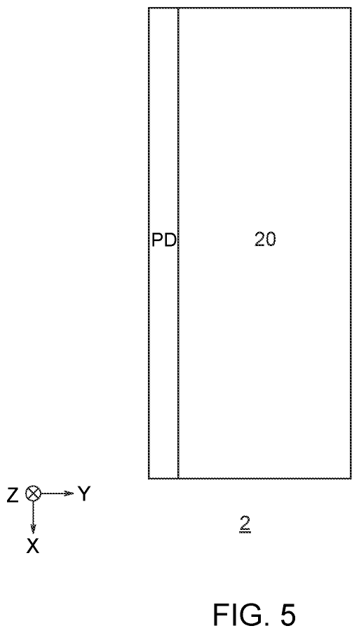

FIG. 5 is a schematic plan view of the array chip 2. The array chip 2 includes a region of the stacked body 20 and a pad region PD. FIG. 5 illustrates a plane surface of the array chip 2 as viewed from the bonding face B1 with the pad region PD in FIG. 1 positioned at the left.

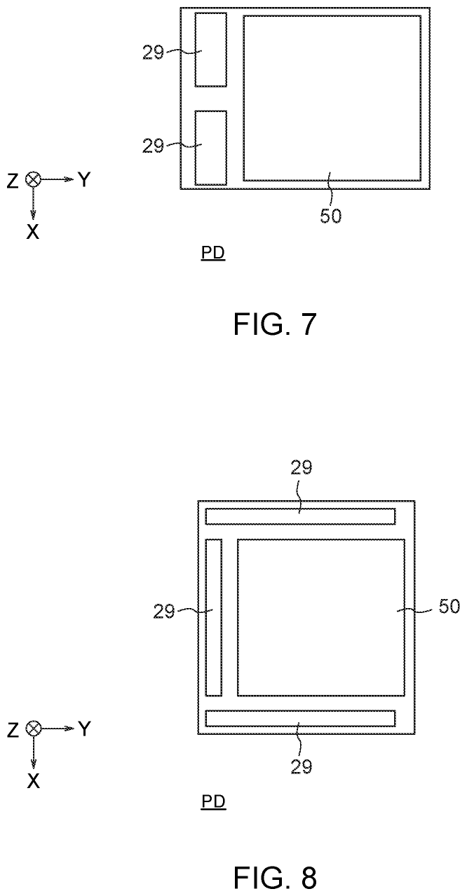

The pad region PD is provided to electrically connect the array chip 2 to the CMOS chip 3. The contact plugs 29, the bonding pads 50 illustrated in FIGS. 7 and 8, and the like are provided in the pad region PD.

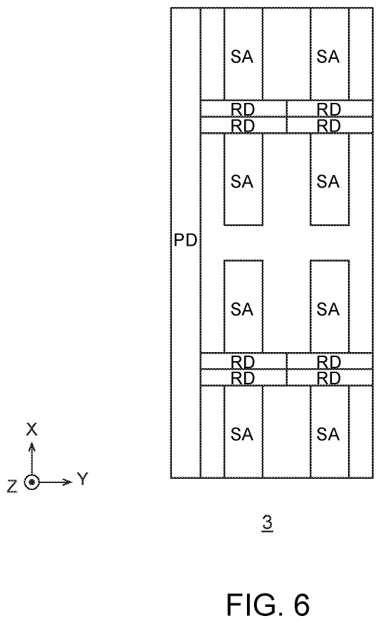

FIG. 6 is a schematic plan view of the CMOS chip 3. FIG. 6 illustrates a plane surface of the CMOS chip 3 as viewed from the bonding face B1 with the pad region PD in FIG. 1 positioned at the left.

The CMOS chip 3 includes CMOS circuits such as sense amplifier circuits SA and row decoder circuits RD. The CMOS chip 3 further includes the pad region PD for electrically connecting the CMOS circuits to the array chip 2. The pad region PD of the CMOS chip 3 can have the same configuration as that of the pad region PD of the array chip 2.

FIGS. 7 and 8 are plan views illustrating arrangement of the contact plugs 29 and the bonding pads 50 provided in the pad region PD of the array chip 2. The pad region PD in FIG. 5 is configured by arraying a plurality of the contact plugs 29 and a plurality of the bonding pads 50 illustrated in FIG. 7 or 8.

The bonding pads 50 are used to be connected (bonded) to the pads of the CMOS chip 3 on the bonding face B1. The bonding pads 50 are electrically connected to the contact plugs 29 along with the lines 24 and can be used to supply the power-supply voltage to the array chip 2 and the CMOS chip 3. A low-resistance metal such as copper or tungsten is used for the bonding pads 50.

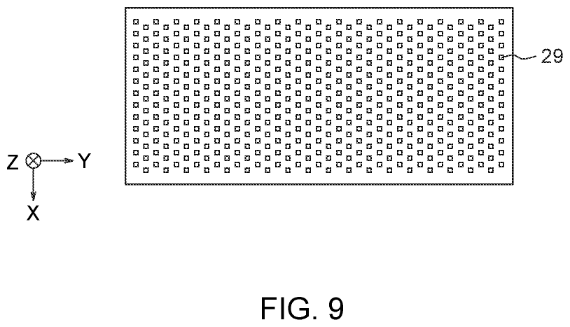

FIG. 9 is a plan view illustrating a region of the contact plugs 29. As illustrated in FIG. 9, the contact plugs 29 are arranged in a zigzag manner to be staggered in the X direction and the Y direction in a planar view as viewed from the Z direction.

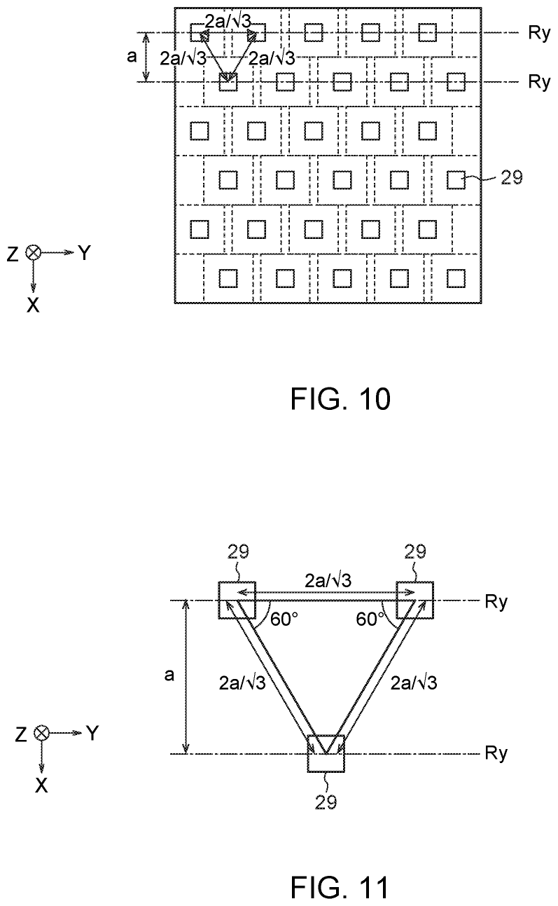

FIG. 10 is a plan view illustrating the arrangement example of the contact plugs 29 in more detail. FIG. 11 is a plan view illustrating an arrangement example of three adjacent contact plugs 29.

The contact plugs 29 are provided between the lines 24 and the bonding pads 50 as illustrated in FIG. 1 and are located around the stacked body 20 of the memory cell array 2m.

The contact plugs 29 are provided to supply the power-supply voltage VDD or the reference voltage VSS to the array chip 2 and the CMOS chip 3. Therefore, to decrease the contact resistance, the contact plugs 29 are arrayed as illustrated in FIGS. 9 and 10 in a planar view as viewed from the Z direction.

In the present embodiment, any of three adjacent contact plugs 29 are arranged to form an equilateral triangle in the X-Y plane as viewed from the Z direction. A plurality of the contact plugs 29 are arrayed in the Y direction to form a contact row Ry. A plurality of the contact rows Ry are arranged in the X direction at equal intervals. When the interval (a second interval) between adjacent contact rows Ry is a, the length (a first interval) of one side of the equilateral triangle formed by three adjacent contact plugs 29 is (⅔^{1/2})×a.

The contact plugs 29 are arranged to be equally spaced at the intervals of (⅔^{1/2})×a in the Y direction in which the word lines WL extend in the X-Y plane. As illustrated in FIG. 11, the contact plugs 29 are arranged to be equally spaced at the intervals of (⅔^{1/2})×a in a direction inclined at an angle of ±60 degrees from the Y direction (an inclined direction at an angle of ±30 degrees with respect to the X direction) in the X-Y plane. That is, the contact plugs 29 are arranged to be equally spaced at the intervals of (⅔^{1/2})×a in the extending direction (the Y direction) of the word lines WL and the inclined direction at the angle of ±60 degrees with respect to the Y direction in the X-Y plane. Accordingly, any of three adjacent contact plugs 29 form an equilateral triangle in the X-Y plane. With this arrangement of any of three adjacent contact plugs 29 in an equilateral triangle, the intervals between adjacent contact plugs 29 are all (⅔^{1/2})×a and equal. Therefore, the contact plugs 29 are arranged more widely in the Y direction than in a case in which the contact plugs 29 are arrayed in a matrix at intervals of “a” in the X direction and the Y direction.

The contact plugs 29 are formed in the same process and at the same time as the contact plugs CCw. The contact plugs 29 are provided at a higher density than the contact plugs CCw in order to decrease the resistance for use in power supply. Therefore, if the contact plugs 29 are arrayed in a matrix at the intervals of “a” in both the X direction and the Y direction, the contact holes for the contact plugs 29 are less likely to be formed to the desired depth than the contact holes for the contact plugs CCw. If overetching is performed to form the contact holes for the contact plugs 29 to sufficiently reach the desired depth, there is a risk that shallow (short) ones of the contact plugs CCw pierce through the electrode films 21 (the word lines WL).

In contrast thereto, according to the present embodiment, the interval between the contact plugs 29 arrayed in the extending direction (the Y direction) of the word lines WL is (⅔^{1/2})×a. Meanwhile, the interval of the contact rows Ry arrayed in the extending direction (the X direction) of the bit lines BL is a. Therefore, the interval between the contact plugs 29 adjacent in the extending direction (the Y direction) of the word lines WL is extended and improved. The density of the contact plugs 29 in the present embodiment is lowered as compared to the case in which the contact plugs 29 are arrayed in a matrix at the intervals of “a” in both the X direction and the Y direction. Accordingly, the contact holes for the contact plugs 29 are easier to form to the desired depth even when formed in the same process and at the same time as the contact holes for the contact plugs CCw, and piercing of the contact holes for the contact plugs CCw through the electrode films 21 (the word lines WL) can be prevented. As described above, according to the present embodiment, the contact plugs 29 and CCw with different depths and different densities can be easily formed.

The contact plugs 29 are arranged evenly in the X-Y plane. With the even arrangement of the contact plugs 29, the contact holes for the contact plugs 29 can be formed linearly along the Z direction. That is, the contact plugs 29 can be prevented from being formed in a curved manner with respect to the Z direction.

In the present embodiment, the interval between the contact plugs 29 arrayed in the extending direction (the Y direction) of the word lines WL is (⅔^{1/2})×a. Meanwhile, the interval between the contact rows Ry arrayed in the extending direction (the X direction) of the bit lines BL is a. Therefore, in the semiconductor storage device 1 according to the present embodiment, the interval of the contact plugs 29 adjacent in the extending direction (the Y direction) of the word lines WL is larger than the interval of the contact plugs 29 adjacent in the extending direction (the X direction) of the bit lines BL and is improved. The stepped portions 2s are provided in the extending direction of the word lines WL as illustrated in FIG. 1 or 2, and the contact plugs CCw connected to the word lines WL are provided on the end parts of the stacked body 20. Therefore, the semiconductor storage device 1 is designed to have a margin in the layout in the extending direction of the word lines WL. Accordingly, by widening the interval between the contact plugs 29 not in the extending direction (the X direction) of the bit lines BL but in the extending direction (the Y direction) of the word lines WL, the density of the contact plugs 29 can be decreased without increasing the chip size.

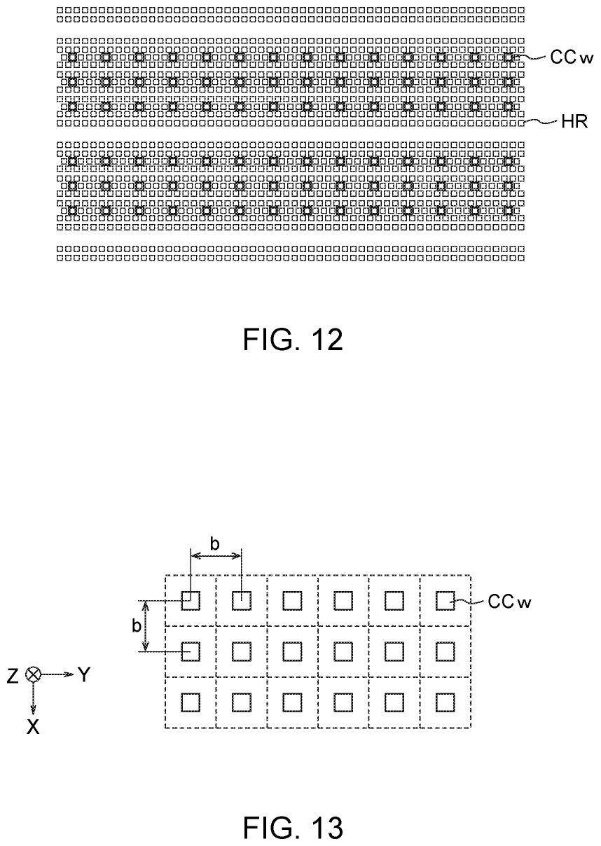

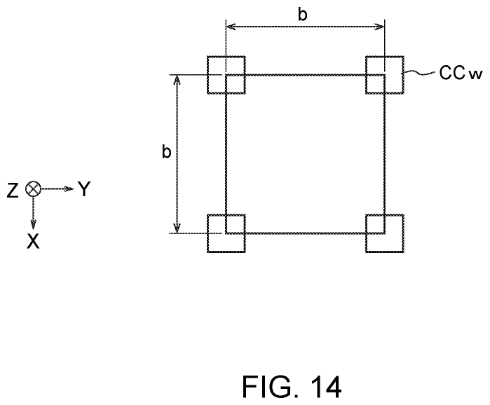

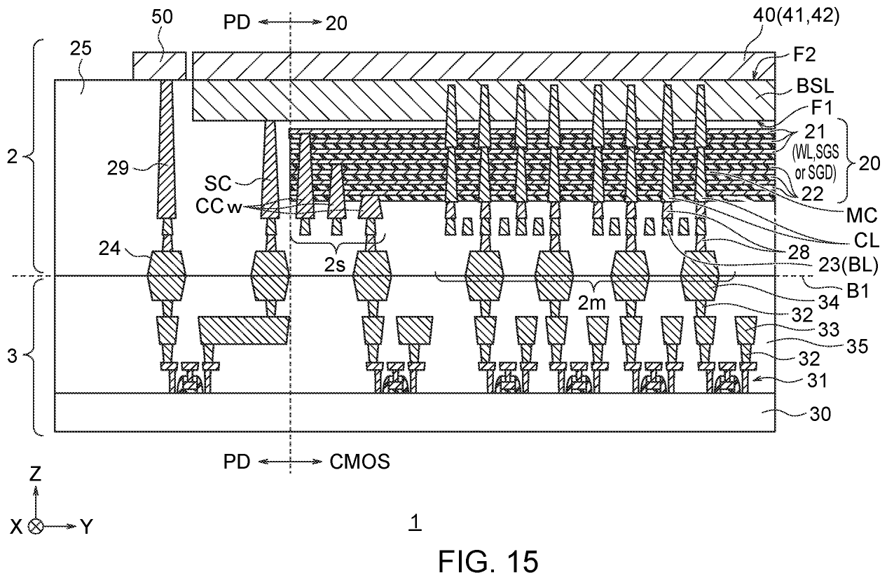

FIG. 12 is a plan view illustrating an arrangement example of the contact plugs CCw connected to the word lines WL at the stepped portions 2s, and supporting posts HR. FIG. 13 is a plan view illustrating an arrangement example of the contact plugs CCw. FIG. 14 is a plan view illustrating an arrangement example of four adjacent contact plugs CCw.

The contact plugs CCw are provided in the region of the array chip 2 corresponding to the region of the row decoders RD in FIG. 6. The contact plugs CCw extend in the Z direction in the interlayer dielectric film 25 illustrated in FIG. 1 and are each connected to an associated one of the electrode films 21 (the word lines WL). The contact plugs CCw are electrically connected to the row decoders RD of the CMOS chip 3 via a wiring layer at the stepped portions 2s. Accordingly, the row decoders RD can selectively apply a word line voltage to the electrode films 21 via the contact plugs CCw.

The supporting posts HR in FIG. 12 are located around the contact plugs CCw. The supporting posts HR are provided to prevent the insulating films 22 from being distorted or falling by gravity in the replacement process in which sacrificial films are replaced by the electrode films 21. For example, a silicon dioxide film is used for the supporting posts HR.

The contact plugs CCw are arranged to be equally spaced at intervals (third intervals) of “b” in the X direction and are arranged to be equally spaced at the intervals of “b” in the Y direction as illustrated in FIGS. 13 and 14. That is, the contact plugs CCw are arranged in a matrix to be equally spaced at the intervals of “b” in the X direction and the Y direction. The interval of “b” can be equal to the interval of “a”. Alternatively, the interval of “b” may be different from the interval of “a”.

The contact plugs CCw are provided to transmit a voltage to the word lines WL and may be at a higher resistance than the contact plugs 29. Therefore, the contact plugs CCw are arrayed in less than five columns or in less than five rows. For example, in FIG. 13, the contact plugs CCw are arrayed in six columns and three rows. Alternatively, the contact plugs CCw may be arrayed in three columns and six rows.

As described above, the contact plugs CCw are arrayed in less than five columns or less than five rows and are arrayed in relatively less columns or rows than the contact plugs 29. The contact plugs 29 are arrayed in five or more columns and five and more rows to provide a low resistance. Accordingly, when the contact plugs 29 are attempted to be formed at a high density in the X-Y plane, a process gas around the contact holes for the contact plugs 29 is likely to become insufficient in an etching process at the time of formation of the contact holes. Meanwhile, since the contact plugs CCw are arrayed in five or less columns or five or less rows, a process gas is less likely to become insufficient in an etching process at the time of formation of the contact holes for the contact plugs CCw even when the contact plugs CCw are formed at a high density in the X-Y plane.

In the present embodiment, any of four adjacent contact plugs CCw are arranged to form a square in the X-Y plane as viewed from the Z direction as illustrated in FIG. 14. The length of one side of the square is the interval of “b” described above. In a case in which the interval of “b” is equal to or less than the interval of “a”, the contact plugs CCw are arranged at a higher density than the contact plugs 29. Even when the contact plugs CCw are arrayed at a relatively high density in this way, the process gas for etching is less likely to become insufficient in the process of forming the contact plugs CCw because the contact plugs CCw are arrayed in five or less columns or five or less rows. Therefore, the contact plugs CCw can be easily formed to any depth.

As described above, according to the present embodiment, the contact plugs 29 provided on the bonding pads 50 are arranged to form an equilateral triangle in the X-Y plane as viewed from the Z direction. Meanwhile, the contact plugs CCw provided on the electrode films 21 at the stepped portions 2s are arranged to form a square in the X-Y plane as viewed from the Z direction. The contact plugs 29 are formed to be deeper and at a higher density than the contact plugs CCw. Therefore, with decrease of the density of the contact plugs 29 in the planar layout, the contact plugs 29 can be formed deeply and piercing of the contact plugs CCw through the electrode films 21 can be prevented.

The contact plugs 29 are evenly arranged in equilateral triangles in the X-Y plane and the contact plugs CCw are evenly arranged in squares in the X-Y plane. Since the contact plugs 29 and CCw are both evenly arranged in this way, curvature thereof in the Z direction can be prevented.

### Second Embodiment

FIG. 15 is a sectional view illustrating a configuration example of the semiconductor storage device 1 according to a second embodiment. In the second embodiment, the stepped portions 2s are not provided at the end parts of the stacked body 20. The contact plugs CCw penetrate through a part of the stacked body 20 to be each connected to any of the electrode films 21 at the end parts of the stacked body 20. In this case, the end parts of the stacked body 20 are not processed stepwise. The contact plugs CCw are formed in contact holes each reaching any of the electrode films 21 not in the interlayer dielectric film 25 but in the stacked body 20.

The rest of the configuration of the semiconductor storage device 1 according to the second embodiment may be identical to that in the first embodiment. Accordingly, the second embodiment can obtain effects identical to those of the first embodiment.

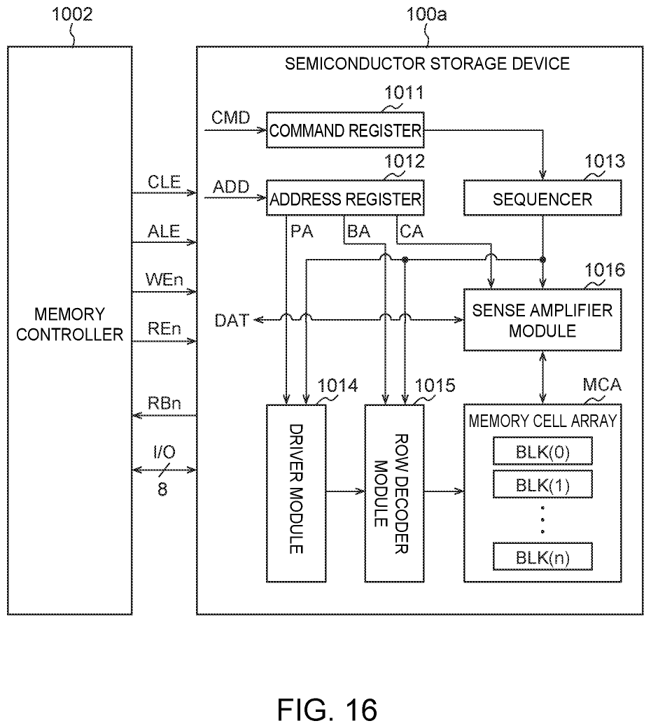

FIG. 16 is a block diagram illustrating a configuration example of a semiconductor storage device to which any of the embodiments described above is applied. The semiconductor storage device 1 is, for example, a memory 100a such as a NAND flash memory that can store data in a nonvolatile manner and is controlled by an external memory controller 1002. Communications between the memory 100a and the memory controller 1002 support, for example, NAND interface standards.

As illustrated in FIG. 16, the memory 100a includes, for example, a memory cell array MCA, a command register 1011, an address register 1012, a sequencer 1013, a driver module 1014, a row decoder module 1015, and a sense amplifier module 1016.

The memory cell array MCA includes a plurality of blocks BLK(0) to BLK(n) (n is an integer equal to or more than one). The block BLK is a set of a plurality of memory cells that can store therein data in a nonvolatile manner and is used as, for example, a unit of data erasing. A plurality of bit lines and a plurality of word lines are provided in the memory cell array MCA. Each of the memory cells is associated with, for example, one bit line and one word line. A detailed configuration of the memory cell array MCA will be described later.

The command register 1011 retains a command CMD received by the memory 100a from the memory controller 1002. The command CMD includes, for example, a command for causing the sequencer 1013 to perform an operation such as a read operation, a write operation, or an erase operation.

The address register 1012 retains address information ADD received by the memory 100a from the memory controller 1002. The address information ADD includes, for example, a block address BA, a page address PA, and a column address CA. For example, the block address BA, the page address PA, and the column address CA are used for selection of a block BLK, a word line, and a bit line, respectively.

The sequencer 1013 controls the entire operation of the memory 100a. For example, the sequencer 1013 controls the driver module 1014, the row decoder module 1015, the sense amplifier module 1016, or the like in accordance with the command CMD retained in the command register 1011 to perform an operation such as a read operation, a write operation, or an erase operation.

The driver module 1014 generates a voltage to be used in an operation such as a read operation, a write operation, or an erase operation. The driver module 1014 applies the generated voltage, for example, to a signal line corresponding to a word line selected in accordance with the page address PA that is retained in the address register 1012.

The row decoder module 1015 includes a plurality of row decoders. The row decoders select one of the blocks BLK in the corresponding memory cell array MCA in accordance with the block address BA retained in the address register 1012. The row decoders transfer, for example, the voltage that is applied to the signal line corresponding to the selected word line, to the selected word line in the selected block BLK.

In a write operation, the sense amplifier module 1016 applies a desired voltage to each bit line according to data DAT to be written, which is received from the memory controller 1002. In a read operation, the sense amplifier module 1016 determines data stored in the memory cells on the basis of the voltages of the bit lines and transfers the determination result as read data DAT to the memory controller 1002.

A combination of the memory 100a and the memory controller 1002 explained above may constitute one semiconductor storage device. Examples of the semiconductor storage device include a memory card such as an SD™ card and an SSD (solid state drive).

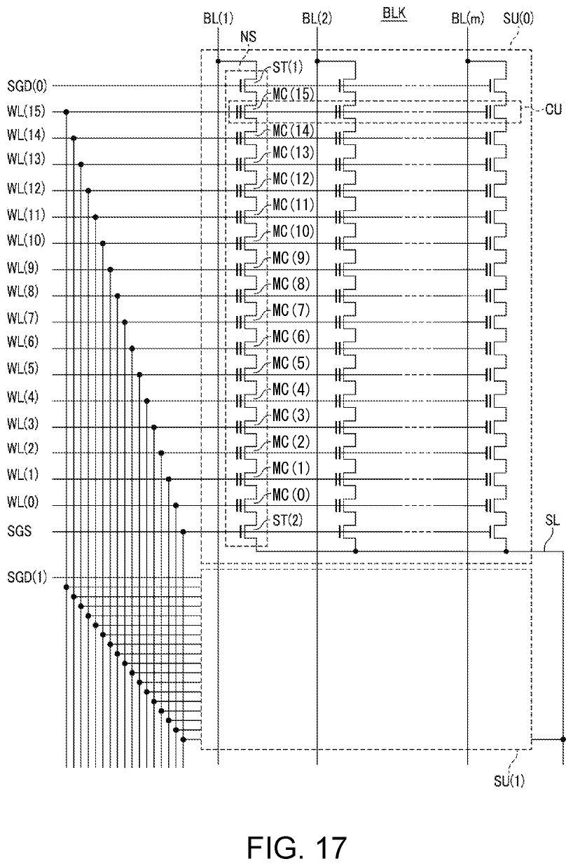

FIG. 17 is a circuit diagram illustrating an example of the circuit configuration of the memory cell array MCA. One block BLK is extracted from the blocks BLK included in the memory cell array MCA. As illustrated in FIG. 17, each block BLK includes a plurality of string units SU (0) to SU (k) (k is an integer equal to or more than one).

Each string unit SU includes a plurality of NAND strings NS each associated with one of the bit lines BL(0) to BL(m) (m is an integer equal to or more than one). Each NAND string NS includes, for example, memory cells MC(0) to MC(15), and selection transistors ST(1) and ST(2). Each memory cell MC includes a control gate and a charge accumulating layer and retains data in a nonvolatile manner. Each of the selection transistors ST(1) and ST(2) is used to select the string unit SU at the time of various operations.

In each NAND string NS, the memory cells MC(0) to MC(15) are connected in series. The drain of the selection transistor ST(1) is connected to the associated bit line BL, and the source of the selection transistor ST(1) is connected to one end of the series-connected memory cells MC(0) to MC(15). The drain of the selection transistor ST(2) is connected to the other end of the series-connected memory cells MC(0) to MC(15). The source of the selection transistor ST(2) is connected to a source line SL.

The control gates of each of the memory cells MC(0) to MC(15) in the same block BLK are connected in common to the associated one of the word lines WL (0) to WL (15). The gates of the selection transistors ST(1) in each of the string units SU (0) to SU (k) are connected in common to the associated one of selection gate lines SGD (0) to SGD (k). The gates of the selection transistors ST(2) are connected in common to a selection gate line SGS.

In the circuit configuration of the memory cell array MCA described above, each of the bit lines BL is shared by the NAND string NS to which the same column address is assigned in each of the string units SU. The source line SL is shared by, for example, a plurality of the blocks BLK.

A set of the memory cells MC connected to a common word line WL in one string unit SU is referred to as, for example, “cell unit CU”. For example, the storage capacity of the cell unit CU including memory cells MC each storing therein one-bit data is defined as “one page data”. The cell unit CU can have the storage capacity of two or more page data according to the number of bits in data that can be stored in one memory cell MC.

The memory cell array MCA included in the memory 100a according to the present embodiment is not limited to the circuit configuration described above. For example, the number of the memory cells MC and the number of the selection transistors ST(1) and ST(2) included in each of the NAND strings NS can be each designed to any number. The number of the string units SU included in each of the blocks BLK can be designed to any number.

While embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a stacked body comprising a plurality of first conducting films and a plurality of first insulating films alternately stacked in a first direction;
a plurality of columnar bodies each comprising a first semiconductor part extending in the first direction in the stacked body, and a first insulator part located between the first semiconductor part and the stacked body;
a transistor located in the first direction of the stacked body; and
a plurality of first conductors extending in the first direction and connected to the transistor, wherein
three adjacent ones of the first conductors are arranged to form an equilateral triangle in a first plane orthogonal to the first direction.

2. The device of claim 1, wherein the first conductors are arranged to be equally spaced at first intervals in a second direction in which the first conducting films extend in the first plane, and are arranged to be equally spaced at the first intervals in a direction inclined at 60 degrees from the second direction in the first plane.

3. The device of claim 2, wherein a plurality of arrays of the first conductors arrayed in the second direction are arranged to be equally spaced at second intervals in a third direction orthogonal to the first and second directions in the first plane.

4. The device of claim 3, wherein the first interval is (⅔^{1/2})×a when the second interval is a.

5. The device of claim 3, wherein the first interval is larger than the second interval.

6. The device of claim 4, wherein the first interval is larger than the second interval.

7. The device of claim 1, wherein the first conducting films are word lines.

8. The device of claim 1, further comprising a plurality of second conductors extending in the first direction and each being connected to an associated one of the first conducting films, wherein
four adjacent ones of the second conductors are arranged to form a square in a first plane orthogonal to the first direction.

9. The device of claim 2, further comprising a plurality of second conductors extending in the first direction and each being connected to an associated one of the first conducting films, wherein
four adjacent ones of the second conductors are arranged to form a square in a first plane orthogonal to the first direction.

10. The device of claim 3, further comprising a plurality of second conductors extending in the first direction and each being connected to an associated one of the first conducting films, wherein
four adjacent ones of the second conductors are arranged to form a square in a first plane orthogonal to the first direction.

11. The device of claim 4, further comprising a plurality of second conductors extending in the first direction and each being connected to an associated one of the first conducting films, wherein
four adjacent ones of the second conductors are arranged to form a square in a first plane orthogonal to the first direction.

12. The device of claim 8, wherein the second conductors are arranged to be equally spaced at third intervals in a second direction in which the first conducting films extend, and are arrayed to be equally spaced at the third intervals in a third direction orthogonal to the first and second directions in the first plane.

13. The device of claim 12, wherein the third interval is equal to the second interval.

14. The device of claim 1, further comprising a bonding pad located on one ends of the first conductors.

15. The device of claim 1, wherein a first chip comprising the stacked body, the columnar bodies, and the first conductors is bonded to a second chip comprising the transistor to be electrically connected to the second chip.

16. The device of claim 8, wherein
the stacked body comprises a stepped portion formed stepwise, and
the second conductors are each connected to an associated one of the first conducting films at the stepped portion.

17. The device of claim 16, further comprising a second insulating film located on the stepped portion, wherein
the second conductors are located to extend in the first direction in the second insulating film.

18. The device of claim 8, wherein the second conductors are each connected to any one of the first conducting films through a part of the stacked body.
